(19) United States
(12) Patent Application Publication
(10) Pub. No.: US 2011/0241151 A1
(43) Pub. Date: Oct. 6, 2011

(54) IMAGING DEVICE

(75) Inventors: Toshihiro NAKATANI, Kanagawa (JP); Yuuki IMADA, Kanagawa (JP); Takashi GOTO, Kanagawa (JP)

(73) Assignee: FUJIFILM CORPORATION, Tokyo (JP)

(21) Appl. No.: 13/074,757

(22) Filed: Mar. 29, 2011

(30) Foreign Application Priority Data
Mar. 31, 2010 (JP) 2010-084410
Mar. 8, 2011 (JP) 2011-050651

(51) Int. Cl. H01L 31/14

(52) U.S. Cl. 257/443; 257/E31.097

(57) ABSTRACT

An imaging device includes a plurality of lower electrodes, an upper electrode, an organic photoelectric conversion layer and a passivation layer. The plurality of lower electrodes are arranged in a two dimensional pattern above a substrate. The upper electrode is arranged above the plurality of lower electrodes so as to oppose the lower electrodes. The organic photoelectric conversion layer is sandwiched between the plurality of lower electrodes and the upper electrode. The passivation layer is provided above the upper electrode and covers the upper electrode. An angle which an end side surface of the lower electrode forms with respect to a surface of a lower layer supporting the lower electrode is 45-degree or more. The passivation layer is formed from a plurality of layers. Film stress of the entire passivation layer ranges from −200 MPa to 250 MPa.

### CROSS-REFERENCE TO RELATED APPLICATIONS

This application claims the benefit of Japanese Patent Application Nos. 2010-084410, filed on Mar. 31, 2010, and 2011-050651 filed on Mar. 8, 2011, the entire contents of which are hereby incorporated by reference, the same as if set forth at length; the entire of which are incorporated herein by reference.

### BACKGROUND OF THE INVENTION

1. Technical Field

The present invention relates to an imaging device.

2. Description of Related Art

A CCD imaging device and a CMOS imaging device have hitherto been known as image sensors utilized in a digital still camera, a digital video camera, a camera for use in a portable phone, an endoscopic camera, and others.

In the CCD imaging device and the CMOS imaging device, not only a photoelectric conversion block like a photodiode, but also a signal read circuit and an interconnection associated therewith are usually formed for each of pixels on a semiconductor substrate. With an increasing progress in miniaturization of a pixel, a proportion of read circuit/interconnection region occupying in one pixel becomes relatively greater, while a light receiving area of the photoelectric conversion section eventually becomes smaller. An aperture ratio becomes smaller, and sensitivity of an imaging device decreases.

A currently-proposed stacked imaging device includes a photoelectric conversion layer formed above a semiconductor substrate on which read circuits and interconnections are formed, thereby enhancing an aperture ratio. By way of example, a stacked imaging device includes a pixel electrode (a lower electrode) formed above a substrate, a counter electrode (an upper electrode) formed above the pixel electrode, and a photoelectric conversion layer and a charge blocking layer interposed between the electrodes. The photoelectric conversion layer and the charge blocking layer can be formed from an organic material. A stacked imaging device having a photoelectric conversion layer using an organic material is described in JP-A-2008-252004.

An organic material is usually degraded by infiltration of oxygen and water. Therefore, a stacked imaging device using an organic material requires a passivation layer that blocks infiltration of oxygen and water. Incidentally, since the passivation layer exhibits large internal stress, white flaw defects arise as a result of infliction of damage to a counter electrode, a photoelectric conversion layer, and a blocking layer. Therefore, decreasing internal stress of the passivation layer is required to prevent deterioration of element performance.

Not only an imaging device but also an organic EL element having an organic luminescent material sandwiched between a pair of mutually opposing electrodes on its substrate have hitherto been known as an element having an organic element and an electrode (see JP-A-2001-284042). The organic EL element described in connection with JP-A-2001-284042 has, on a surface of the organic luminescent material, a protective layer corresponding to a passivation layer. The protective layer is formed by stacking layers that internally generate different levels of stress. Internal stress of the protective layer is eased by the configuration.

### SUMMARY

In the stacked imaging device, the internal stress of the passivation layer concentrates on a neighborhood of a step located at an edge of the pixel electrode. The stress concentrated on the neighborhood of the step exerts on the layer that is situated above the step and that includes the organic material, whereupon damage is inflicted on the organic material. There has been no knowledge about a degree of easing of the internal stress of the passivation layer that prevents infliction of damage to the organic material, which would otherwise be caused by the step at the edge of the pixel electrode.

The present invention provides an imaging device capable of thoroughly inhibiting occurrence of white flaw defects.

An imaging device includes a plurality of lower electrodes, an upper electrode, an organic photoelectric conversion layer and a passivation layer. The plurality of lower electrodes are arranged in a two dimensional pattern above a substrate. The upper electrode is arranged above the plurality of lower electrodes so as to oppose the lower electrodes. The organic photoelectric conversion layer is sandwiched between the plurality of lower electrodes and the upper electrode. The passivation layer is provided above the upper electrode and covers the upper electrode. An angle which an end side surface of the lower electrode forms with respect to a surface of a lower layer supporting the lower electrode is 45-degree or more. The passivation layer is formed from a plurality of layers. Film stress of the entire passivation layer ranges from −200 MPa to 250 MPa.

In the imaging device, when the angle which the end side surface of the lower electrode forms with respect to the surface of the lower surface supporting the lower electrode is 45-degree or more, it is possible to prevent infliction of damage to an organic material of the photoelectric conversion layer, which would otherwise caused by stress of the passivation layer, so long as the film stress of the entire passivation layer is eased to −200 MPa to 250 MPa or thereabouts, so that occurrence of white flaw defects can be prevented without fail.

The present invention makes it possible to provide an imaging device capable of inhibiting occurrence of white flaw defects without fail.

### BRIEF DESCRIPTION OF THE DRAWINGS

FIG. 1 is a cross sectional schematic view showing a configuration of an imaging device.

FIG. 2 is a schematic cross sectional view showing a configuration of an organic layer, an upper electrode, and a passivation layer in one example of an imaging device.

FIG. 3 is a schematic cross sectional view showing a configuration of an organic layer, an upper electrode, and a passivation layer in another example of an imaging device.

FIG. 4 is a cross sectional view showing a configuration of an insulation layer and a pixel electrode in the imaging device shown in FIG. 1.

FIG. 5 is a graph showing a relationship between film stress of a passivation layer and white flaw defects.

### DETAILED DESCRIPTION OF EMBODIMENTS OF THE INVENTION

An example configuration of an imaging device is first described.

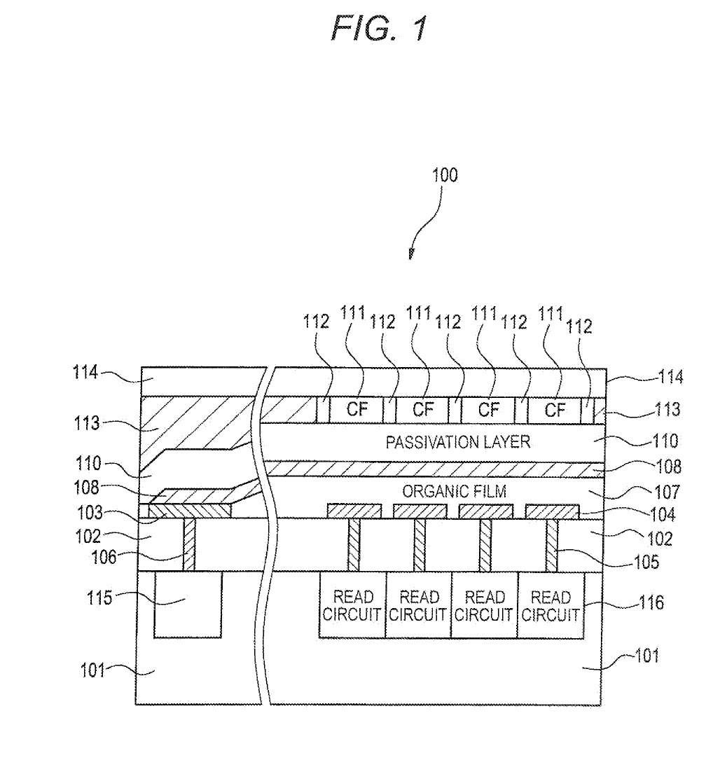

FIG. 1 is a cross sectional schematic view showing a configuration of a stacked imaging device.

An imaging device 100 shown in FIG. 1 includes a substrate 101, an insulation layer 102, a connection electrode 103, pixel electrodes 104, connection blocks 105, a connection block 106, an organic film 107, a counter electrode 108, a passivation layer 110, color filters 111, partitions 112, a light blocking layer 113, a protective layer 114, a counter electrode voltage feed block 115, and read circuits 116.

The substrate 101 is a glass substrate or a semiconductor substrate like Si. The insulation layer 102 is formed over the substrate 101. The plurality of pixel electrodes 104 arranged in a two dimensional pattern when surfaces of the pixel electrodes are viewed in the vertical direction are formed on the insulation layer 102. The connection electrode 103 is formed on the insulation layer 102. The connection electrode 103 and the plurality of pixel electrodes 104 are respectively situated on the surface of the insulation layer 102. A lower surface of the connection electrode 103 and lower surfaces of the respective pixel electrodes 104 are substantially flush with the surface of the insulation layer 102. The pixel electrodes 104 are electric charge collection electrodes for collecting electric charges developed in a photoelectric conversion layer of the organic film 107 to be described later.

The read circuits 116 connected respectively to the plurality of pixel electrodes 104 and the counter electrode voltage feed block 115 connected to the connection electrode 103 are formed in the substrate 101.

The organic film 107 is formed over the insulation layer 102 and the respective pixel electrodes 104. The organic film 107 includes the photoelectric conversion layer. The photoelectric conversion layer is a layer that generates electric charges by photoelectric conversion of incident light. The organic film 107 is provided over the plurality of pixel electrodes 104 so as to cover the plurality of pixel electrodes 104. While the organic film 107 has a constant film thickness on each of the pixel electrodes 104, the film thickness of the organic film 107 may also change outside the pixel block (outside an effective pixel region). The organic film 107 is described in detail later. The organic film 107 may include an inorganic material layer as well as a layer formed solely from an organic material.

The counter electrode 108 is a single electrode opposing the plurality of respective pixel electrodes 104. The counter electrode 108 is laid on the organic film 107. In order to let light enter the organic film 107, the counter electrode 108 is formed from a conductive material that is transparent to incident light.

The counter electrode 108 is laid on the organic film 107. And, the counter electrode 108 is formed so as to extend over the connection electrode 103 disposed outside an outer edge of the organic film 107 on the insulation layer 102 and is electrically connected to the connection electrode 103.

The connection blocks 105 and 106 are embedded in the insulation layer 102. The connection blocks 105 electrically connect the pixel electrodes 104 to the respective read circuits 116. The connection block 106 electrically connects the connection electrode 103 to the counter electrode voltage feed block 115. The connection blocks 105 and 106 are pillar-shaped members formed from a conductive material; for instance, via plugs.

The counter electrode voltage feed block 115 is formed in the substrate 101 and applies a predetermined voltage to the counter electrode 108 by way of the connection block 106 and the connection electrode 103. When a voltage to be applied to the counter electrode 108 is higher than a source voltage of the imaging device 100, the source voltage is boosted by means of an unillustrated booster circuit, like a charge pump, thereby feeding the predetermined voltage.

The read circuits 116 are provided in the substrate 101 so as to correspond to the plurality of respective pixel electrodes 104. The read circuits 116 each read signals commensurate with electric charges collected by the respective pixel electrodes 104. Each of the read circuits 116 is formed from a CMOS circuit. The read circuits 116 are shielded from light by means of an unillustrated light block layer provided on the insulation layer 102. Adopting a CCD circuit or a CMOS circuit for a common application of an image sensor is desirable. From the viewpoint of a high speed characteristic, adopting a CMOS circuit is preferable. The read circuit 116 may also be formed from a CCD circuit, a TFT circuit, and the like.

The passivation layer 110 is formed over the counter electrode 108. The passivation layer 110 hinders infiltration of oxygen and water into the organic film 107 by blocking oxygen and water. The passivation layer 110 is formed from a plurality of layers. Further, film stress of the entire passivation layer 110 lies in a predetermined range.

The plurality of color filters 111 arranged in a two dimensional pattern are formed over the passivation layer 110. The plurality of color filters 111 are formed at elevated positions above the respective pixel electrodes 104.

The partitions 112 are formed in a grid pattern and separate the adjacent color filters 111 from each other, to thus be able to inhibit entry of incident light into the color filters of other pixel blocks. Thus, the partitions enhance light transmission efficiency of each of the pixel blocks.

The light blocking layer 113 is formed except areas where the color filters 111 and the partitions 112 are provided on the passivation layer 110. The light blocking layer 113 prevents entry of light into a region of the organic film 107 covering an area except areas where the plurality of pixel electrodes 104 are arranged.

The protective layer 114 is formed so as to cover the color filters 111, the partitions 112, and the light blocking layer 113 and protects a light entrance surface of the imaging device.

Details of the passivation layer 110, the color filters 111, the partitions 112, and the light blocking layer 113 are described later.

Each of the connection electrode 103, the connection block 106, and the counter electrode voltage feed block 115 can also be provided in numbers or one at a time. When the counter electrode voltage feed block 115 is provided in numbers, the counter electrode voltage feed blocks 115 will be disposed so as to become symmetry with respect to the center of the counter electrode 108. A voltage is fed to the counter electrode 108 from the respective counter electrode voltage feed blocks 115, thereby hindering occurrence of a voltage drop in the counter electrode 108.

In the imaging device 100, an area including at least one pixel electrode 104, the organic film 107, and the counter electrode 108 opposing the pixel electrode 104 can be defined as one pixel block. The imaging device 100 corresponds to a plurality of arrayed pixel blocks. One pixel electrode 104 and the counter electrode 108 located above the pixel electrode 104 pair up with each other. The organic film 107 sandwiched between the pair of electrodes acts as an organic photoelectric conversion element. Each of the pixel blocks includes the organic photoelectric conversion element.

The passivation layer in a solid-state imaging device is now described.

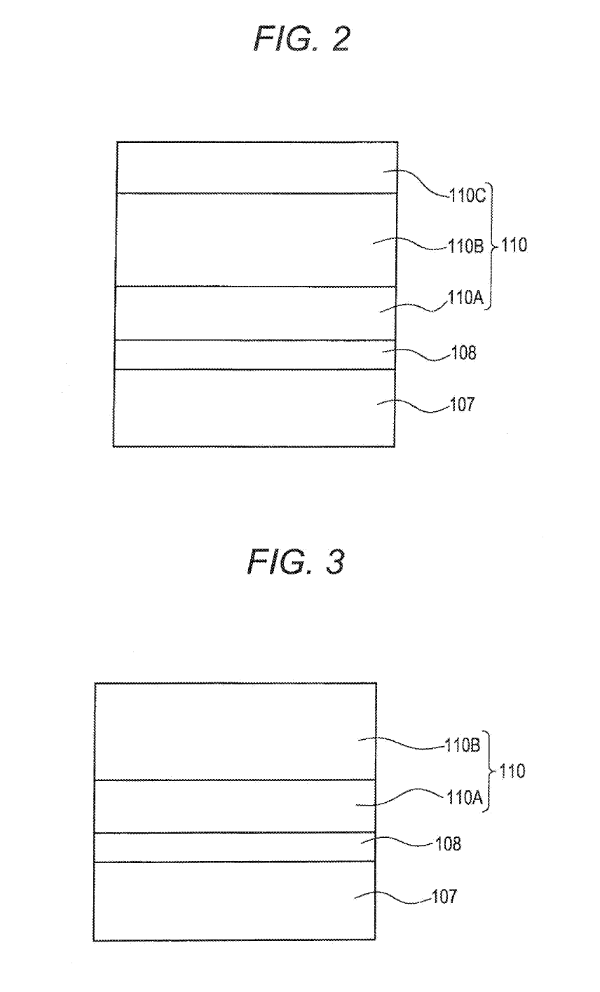

FIG. 2 is a schematic cross sectional view showing a configuration of the organic film, the counter electrode, and the passivation layer in the imaging device shown in FIG. 1.

The passivation layer 110 has a configuration in which a first layer 110A, a second layer 110B, and a third layer 110C are stacked in this sequence on the counter electrode 108. The first layer 110A and the third layer 110C are layers that primarily exhibit stress easing function for easing film stress inflicted on the entire passivation layer 110. The second layer 110B primarily exhibits sealing function for blocking oxygen and water.

An explanation is now given to film stress inflicted on the entire passivation layer 110 when the passivation layer 110 is configured by stacking in sequence the first layer 110A including silicon oxynitride (hereinafter also labeled SiON), the second layer 110B including aluminum oxide (hereinafter also labeled AlO), and the third layer 110C including SiON. Compressive stress is inflicted on the first layer 110A and the third layer 110C, which are made of SiON, in a direction perpendicular to a thickness direction of the passivation layer 110 (i.e., a horizontal direction in the drawing). In the meantime, tensile stress is inflicted on the second layer 110B which is made of AlO in a direction perpendicular to the thickness direction of the passivation layer 110. The film stresses cancel each other along an interfacial surface between the first layer 110A and the second layer 110B and an interfacial surface between the second layer 110B and the third layer 110C. The film stress inflicted on the entire passivation layer 110 can be confined to a predetermined range, so that physical damage inflicted on the organic film 107 and the organic photoelectric conversion layer can be suppressed. The first layer 110A and the third layer 110C are not limited to silicon oxynitride film. The essential requirement for these layers is to select any one from the silicon oxynitride film, an aluminum oxide film, and a silicon oxide film (hereinafter also labeled SiO).

FIG. 3 shows another example configuration of the passivation layer 110 shown in FIG. 2. As illustrated in the example configuration, the passivation layer 110 can be formed from two layers. In the example configuration, the passivation layer 110 is configured by stacking the first layer 110A including silicon oxynitride and the second layer 110B including aluminum oxide, in this sequence, on the counter electrode 108. The film stresses cancel each other along the interfacial surface between the first layer 110A and the second layer 110B. The film stress inflicted on the entire passivation layer 110 can thus be confined to a predetermined range, so that physical damage inflicted on the organic film 107 and the organic photoelectric conversion layer can be suppressed.

The configuration of the foregoing passivation layer 110 is an example. The configuration of the passivation layer 110 can be changed, as required, within a range where internal stress in the entire passivation layer 110 can be confined to the predetermined range by cancelling the film stresses along the interfacial surfaces between superposed layers among the plurality of layers. The passivation layer 110 can also be formed from four layers or more. The essential requirement for the configuration is to pile an AlO film and any one of an SiO film, a SiON film, and a SiN film one over the other on the counter electrode 108.

A thickness of the counter electrode 108 is on the order of 10 nm and sufficiently smaller than a thickness of the passivation layer 110. Therefore, influence resultant of infliction of the internal stress in the counter electrode 108 on the organic film 107 is negligible.

Details of the organic film 107, the pixel electrode 104, the counter electrode 108, and the color filter 111 are now described.

(Organic Film)

In addition to including the organic photoelectric conversion layer, the organic film 107 can include a charge blocking layer.

The charge blocking layer exhibits a function for suppressing a dark current. The charge blocking layer can be formed from a plurality of layers; for instance, a first blocking layer and a second blocking layer. The charge blocking layer is formed from a plurality of layers as mentioned above, whereby an interfacial surface is formed between the first blocking layer and the second blocking layer. Discontinuity occurs in intermediate level existing in each of the layer, thereby posing difficulty in migration of charge carriers by way of the intermediate level, so that the dark current can be restrained. The charge blocking layer may also be embodied as a single layer.

The organic photoelectric conversion layer includes a p-type organic semiconductor and an n-type organic semiconductor. A donor-accepter interfacial surface is formed by joining a p-type organic semiconductor to an n-type organic semiconductor, whereby exciton dissociation efficiency can be increased. Therefore, a photoelectric conversion layer which is formed by joining the p-type organic semiconductor to the n-type organic semiconductor exhibits high photoelectric conversion efficiency. In particular, the organic photoelectric conversion layer mixedly containing the p-type organic semiconductor and the n-type organic semiconductor preferably involves an increase in joint interface to thereby enhance photoelectric conversion efficiency.

P-type organic semiconductors (compounds) are donor organic semiconductors and refer to organic compounds that are primarily typified by hole transporting organic compounds and that exhibit a characteristic of being likely to provide electrons. More specifically, the organic compounds refer to organic compounds that exhibit a low ionization potential when two organic materials are used while remaining in contact with each other. Therefore, any organic compounds can be used as the donor organic compounds, so long as the organic compounds exhibit an electron donating property. There can be used; for instance, triallylamine compounds, benzidine compounds, pyrazoline compounds, styrylamine compounds, hydrazone compounds, triphenylmethane compounds, carbazole compounds, polysilane compounds, thiophene compounds, phthalocyanine compounds, cyanine compounds, merocyanine compounds, oxonol compounds, polyamine compounds, indole compounds, pyrrole compounds, pyrazole compounds, polyarylene compounds, condensed aromatic carbon ring compounds (naphthalene derivatives, anthracene derivatives, phenanthrene derivatives, tetracene derivatives, pyrene derivatives, perylene derivatives, and fluoranthene derivatives), a metal complex having a nitrogen-containing hetero ring compound as a ligand, and the like. The donor organic compounds are not limited to the compounds mentioned above. Organic compounds that are smaller than organic compounds used as n-type (acceptor) compounds in terms of an ionization potential can also be used as the donor organic semiconductors.

N-type organic semiconductors (compounds) correspond to acceptor organic semiconductors and refer to organic compounds that are primarily typified by organic compounds possessing an electron transport property and that have a characteristic of being likely to accept electrons. More specifically, the n-type organic semiconductors refer to organic compounds that exhibit greater electron affinity when two organic compounds are used while remaining in contact with each other. Therefore, any organic compounds can be used as the acceptor organic compounds, so long as the organic compounds exhibit electron acceptability. For instance, there can be mentioned condensed aromatic carbon ring compounds (naphthalene derivatives, anthracene derivatives, phenanthrene derivatives, tetracene derivatives, pyrene derivatives, perylene derivatives, and fluoranthene derivatives); five-member to seven-member hetero ring compounds including nitrogen atoms, oxygen atoms, and sulfur atoms (e.g., pyridine, pyrazine, pyrimidine, pyridazine, triazine, quinoline, quinoxaline, quinazoline, phthalazine, cinnoline, isoquinoline, pteridine, acridine, phenazine, phenanthroline, tetrazole, pyrazole, imidazole, thiazole, oxazole, indazole, benzimidazole, benzotriazole, benzoxazole, benzothiazole, carbazole, purine, triazolopyridazine, triazolopyrimidine, tetrazaindene, oxadiazole, imidazopyridine, pyralizine, pyrrolopyridine, thiadiazolopyridine, dibenzazepine, tribenzazepine, and others); polyarylene compounds; fluorine compounds; cyclopentadiene compounds; silyl compounds; a metal complex having a nitrogen-containing hetero ring compound as a ligand; and others. The acceptor organic compounds are not limited to the organic compounds mentioned above, and, as mentioned above organic compounds that are greater than the organic compounds used as p-type (donor) compounds in terms of electron affinity can also be used as the acceptor organic semiconductors.

Any organic dyes can also be used as the p-type organic semiconductors or the n-type organic semiconductors. Preferably, there are mentioned a cyanine dye, a styryl dye, a hemicyanine dye, a merocyanine dye (including zero-methen merocyanine (simple merocyanine)), a 3-nucleus merocyanine dye, a 4-nucleus merocyanine dye, a rhodacyanine dye, a complex cyanine dye, a complex merocyanine dye, an allopolar dye, an oxonol dye, a hemioxonol dye, a squarylium dye, a croconium dye, an azomethine dye, a coumalin dye, an arylidene dye, an anthraquinone dye, a triphenylmethane dye, an azo dye, an azomethine dye, spiro compounds, a metallocene dye, a fluorenone dye, a fulgide dye, a perylene dye, a perynone dye, a phenazine dye, a phenothiazine dye, a quinine dye, a diphenylmethane dye, a polyene dye, an acridine dye, an acridinone dye, a diphenylamine dye, a quinacridone dye, a quinophthalone dye, a phenoxazine dye, a phthaloperylene dye, a diketopyrrolopyrrole dye, a dioxane dye, a porphyrin dye, a chlorophyll dye, a phthalocyanine dye, a metal complex dye, and condensed aromatic carbon ring dyes (naphthalene derivatives, anthracene derivatives, phenanthrene derivatives, tetracene derivatives, pyrene derivatives, perylene derivatives, and fluoranthene derivatives).

Using fullerene or a fullerene derivative that exhibits superior electron transport property as the n-type organic semiconductor is particularly preferable. Fullerene designates fullerene C₆₀, fullerene C₇₀, fullerene C₇₆, fullerene C₇₈, fullerene C₈₀, fullerene C₈₂, fullerene C₈₄, fullerene C₉₀, fullerene C₉₆, fullerene C₂₄₀, fullerene C₅₄₀, mixed fullerene, and fullerene nanotubes. Further, the fullerene derivatives designate compounds formed by adding substituents to the fullerenes mentioned above.

Substituents of the fullerene derivatives preferably include alkyl groups, aryl groups, or heterocyclic groups. The alkyl groups more preferably include alkyl groups of carbon number 1 to 12. The aryl groups and the heterocyclic groups preferably correspond to a benzene ring, a naphthalene ring, an anthracene ring, a phenanthrene ring, a fluorene ring, a triphenylene ring, a naphthacene ring, a biphenyl ring, a pyrrole ring, a furan ring, a thiophene ring, an imidazole ring, an oxazole ring, a thiazole ring, a pyridine ring, a pyrazine ring, a pyrimidine ring, a pyridazine ring, an indolizine ring, an indole ring, a benzofuran ring, a benzothiophene ring, an isobenzofuran ring, a benzimidazole ring, an imidazopyridine ring, a quinolizine ring, a quinoline ring, a phthalazine ring, a naphthyridine ring, a quinoxaline ring, a quinoxazoline ring, an isoquinoline ring, a carbazole ring, a phenanthridine ring, an acridine ring, a phenanthroline ring, a thianthrene ring, a chromene ring, a xanthene ring, a phenoxatine ring, a phenothiazine ring, or a phenazine ring; more preferably, to a benzene ring, a naphthalene ring, an anthracene ring, a phenanthrene ring, a pyridine ring, an imidazole ring, an oxazole ring, or a thiazole ring; and, particularly preferably, a benzene ring, a naphthalene ring, or a pyridine ring. The aryl groups and the heterocyclic groups can also have an additional substituent, and the substituent can combine together to the extent possible, to thus create a ring. Further, the aryl groups and the heterocyclic groups can also have a plurality of substituents, and the substituents can be identical to each other or different from each other. Moreover, the plurality of substituents can also combine together to the extent possible, to thus create a ring.

When the organic photoelectric conversion layer contains fullerene or a fullerene derivative, electrons caused by photoelectric conversion can quickly be transported to the pixel electrodes 104 or the counter electrode 108 by way of fullerene ions or fullerene derivative ions. When an electron channel is formed while the fullerene ions or the fullerene derivative ions remain in a row, the electron transport property is enhanced, so that high speed response of the photoelectric conversion element becomes feasible. To this end, 40% or more of fullerene or a fullerene derivative is preferably contained in the organic photoelectric conversion layer. However, if fullerene or a fullerene derivative exists too much, the p-type organic semiconductor will become smaller, and the joint interface will also become smaller, which may in turn deteriorate the exciton dissociation efficiency.

When triallylamine compounds described in connection with JP-A-2000-297068 are used as the p-type organic semiconductor to be mixed with fullerene or a fullerene derivative in the organic photoelectric conversion layer, it is particularly preferable that the photoelectric conversion element can exhibit high S/N ratio. If the proportion of fullerene or a fullerene derivative in the organic photoelectric conversion layer is too large, a proportion of the triallylamine compounds will become smaller, which may in turn deteriorate the quantity of incident light absorbed. Since the photoelectric conversion efficiency is thereby reduced, a preferred composition for fullerene or a fullerene derivative contained in the organic photoelectric conversion layer is 85% or less.

An organic material possessing an electron donating property can be used for the first blocking layer and the second blocking layer. Specifically, low molecular materials that can be used include aromatic diamine compounds, like N,N′-bis(3-methylphenyl)-(1,1′-biphenyl)-4,4′-diamine (TPD) and 4,4′-bis[N-(naphthyl)-N-phenyl-amino]biphenyl(α-NPD); oxazole; oxadiazole; triazole; imidazole; imidazolone; stilbene derivatives; pyrazoline derivatives; tetrahydroimidazole; polyarylalkene; butadiene; 4,4′,4″-tris(N-(3-methylphenyl)N-phenylamino)triphenylamine(m-MTDATA); porphin; TPP copper; porphyrin compounds, like phthalocyanine, copper phthalocyanine, and titanium phthalocyanine oxides; triazole derivatives; oxadizazole derivatives; imidazole derivatives; polyarylalkene derivatives; pyrazoline derivatives; pyrazolone derivatives; phenylenediamine derivatives; anylamine derivatives; amino-substituted chalcone derivatives; oxazole derivatives, styrylanthracene derivatives, fluorenone derivatives, hydrazone derivatives; silazane derivatives, and others. Macromolecular materials that can be used include polymers, such as phenylene vinylene, fluorene, carbazole, indole, pyrene, pyrrole, picoline, thiophene, acetylene, and diacetylene; and derivatives thereof. Any compounds rather than the compounds possessing the electron donating property can be used, so long as the compounds possess a sufficient a hole transport property.

Inorganic materials can also be used for the charge blocking layer. In general, the inorganic materials are greater than the organic materials in terms of a dielectric constant. Therefore, when the inorganic materials are used for the charge blocking layer, a larger amount of voltage is applied to the organic photoelectric conversion layer, so that the photoelectric conversion efficiency can be enhanced. Materials that can be used for the charge blocking layer include calcium oxides, chromium oxides, copper-chromium oxides, manganese oxides, cobalt oxides, nickel oxides, copper oxides, copper-gallium oxides, copper-strontium oxides, niobium oxides, molybdenum oxides, copper-indium oxides, silver-indium oxides, iridium oxides, and others.

In the charge blocking layer formed from a plurality of layers, the organic photoelectric conversion layer and an adjoining layer, among the plurality of layers, are preferably layers formed from the same material as that of the p-type organic semiconductor included in the organic photoelectric conversion layer. The same p-type organic semiconductor is used also for the charge blocking layer, thereby preventing formation of an intermediate level in the interfacial surface between the organic photoelectric conversion layer and the adjacent layer and, in turn, making it possible to further reduce the dark current.

When the charge blocking layer corresponds to a single layer, the layer can be realized as a layer formed from an inorganic material. Alternatively, when the charge blocking layer corresponds to a plurality of layers, one or two layers or more can be realized as layers formed from an inorganic material.

(Pixel Electrode)

Each of the pixel electrodes 104 collects electric charges of electrons or positive holes occurred in the organic film 107 including the organic photoelectric conversion layer laid on the pixel electrode 104. The electric charges collected by each of the pixel electrodes 104 is changed into a signal by the corresponding read circuit 116 of the pixel. An image is generated by combination of the signals acquired from the plurality of pixels.

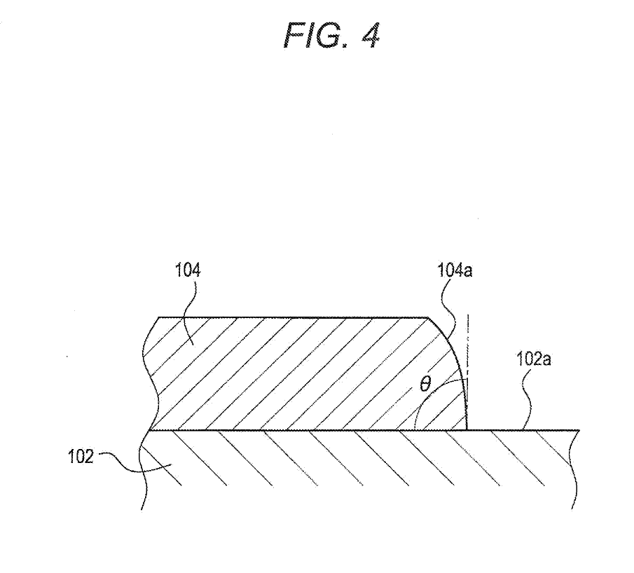

FIG. 4 is a cross sectional view showing a configuration of the insulation layer and the pixel electrode in the imaging device shown in FIG. 1.

In FIG. 4, an angle θ is a tilt angle of an end side surface 104a of the pixel electrode 104 with respect to a surface 102a of the insulation layer 102. The angle θ is equivalent to an angle which a tangential line forms with the surface 102a of the insulation layer 102 in the vicinity of the insulation layer 102 at the end side surface 104a. When the angle θ of the end side surface of the pixel electrode is sharp, the pixel electrode becomes prone to influence of internal stress of the passivation layer 110, and hence white flaw defects become likely to arise. In particular, when the angle θ is 90-degree, the influence of the internal stress of the passivation layer 110 becomes maximum. When the angle θ of the end side surface of the pixel electrode is nearly flat; namely, when the angle θ is close to zero, the pixel electrode is less apt to influence of the internal stress of the passivation layer 110, so that white flaw defects become less likely to arise. When the angle θ is set to 45-degree or more, damage inflicted on the organic material of the organic photoelectric conversion layer by the stress of the passivation layer can be sufficiently reduced, so long as the film stress inflicted on the entire passivation layer is eased to −200 MPa to 250 MPa or thereabouts. Thus, occurrence of white flaw defects can be thoroughly prevented.

When the internal stress inflicted on the end side surface when the angle θ of the end side surface of the pixel electrode is in the vicinity of zero is taken as a reference, the internal stress gradually becomes larger when the angle θ is set to 30-degree or more. When the angle θ is set to 45-degree or more, the internal stress abruptly increases for reasons of concentration of stress on the end side surface of the pixel electrode. For this reason, when the angle θ of the end side surface of the pixel electrode is sharp; namely, 45-degree or more, it will be good enough if occurrence of white flaws can be prevented by means of confining the film stress inflicted on the entire passivation layer to the predetermined range.

From the viewpoint of facilitation of production of the pixel electrodes in the manufacturing process, a preferable angle θ of the end side surface of the pixel electrode is 60-degree or more, and a more preferable angle is 80-degree or more. If the film stress inflicted on the entire passivation layer is eased to about −200 MPa to 250 MPa, no white flow defects occur. In addition, it also becomes possible to design the angle θ of the end side surface of the pixel electrode so as to become sharp, in order to make electrode formation processes easy.

When a noticeable irregularity is present in the surface of the individual pixel electrode 104 at the end of the pixel electrode 104, or minute dust adheres to the pixel electrodes 104, the organic film 107 on the pixel electrode 104 becomes thinner than a desired film thickness or cracked. When the counter electrode 108 is formed on the organic film 107 in such a state, a pixel failure, such as an increase in dark current and a short-circuit, occurs for reasons of the pixel electrode 104 contacting the counter electrode 108 at a defective area or concentration of an electric field.

In order to enhance reliability of the imaging device by preventing occurrence of the defects, a surface roughness Ra of the pixel electrode 104 is preferably 0.6 nm or less. Smaller surface roughness Ra of the pixel electrode 104 means smaller surface irregularities, and superior surface flatness is accomplished. Moreover, in order to eliminate particles on the pixel electrodes 104, it is particularly preferable to cleanse a substrate by means of a common cleansing technique utilized in a semiconductor manufacturing process before formation of the organic film 107.

(Counter Electrode)

The organic film 107 including the organic photoelectric conversion layer is sandwiched between the counter electrode 108 and the pixel electrode 104, thereby applying an electric field to the organic film 107. Further, the counter electrode 108 collects electric charges whose polarity is opposite to that of the signal charges collected by the pixel electrode 104, among the electric charges developed in the organic photoelectric conversion layer. Since collecting the electric charges of opposite polarity does not need to be divided among the pixels, the counter electrode 108 can be made common among the plurality of pixels. For this reason, the counter electrode is often called a common electrode.

In order to let light enter the organic film 107 including the organic photoelectric conversion layer, the counter electrode 108 is preferably made of a transparent conductive film. For instance, metals, metal oxides, metal nitrides, metal borides, organic conductive compounds, and mixtures thereof, are mentioned as a material for the transparent conductive film. Specific example materials for the transparent conductive film include conductive metal oxides, like tin oxides, zinc oxides, indium oxides, indium tin oxides (ITO), indium zinc oxides (IZO), indium tungsten oxides (IWO), and titanium oxides; metal nitrides, like TiN; metals, like gold (Au), platinum (Pt), silver (Ag), chromium (Cr), nickel (Ni), aluminum (Al); mixtures or laminated products formed from the metal and the conductive metal oxide; organic conductive compounds, like polyaniline, polythiophene, polypyrrole; laminated products formed from the organic conductive compound and ITO, and others. A particularly preferred material for the transparent conductive film is any one of ITO, IZO, tin oxides, antimony-doped tin oxides (ATO), fluorine-doped tin oxides (FTO), zinc oxides, antimony-doped zinc oxides (AZO), and gallium-doped zinc oxides (GZO).

When the read circuit 116 is of CMOS type, surface resistance of the counter electrode 108 is preferably 10 kΩ/or less and, more preferably, 1 kΩ/or less. When the read circuit 116 is of CCD type, the surface resistance is preferably 1 kΩ/or less and, more preferably, 0.1 kΩ/or less.

(Color Filter)

Each of the plurality of pixel blocks is provided with the color filter 111. The partitions 112 interposed among the adjacent color filters 111 in the plurality of pixel blocks act as light collection means for collecting light entered the pixel blocks to photoelectric conversion layers in the respective pixel blocks. When a color filter including a color pattern of a first color, a color pattern of a second color, and a color pattern of a third color (three colors; for instance, red, green, and blue) is manufactured, processing pertaining to a light blocking layer producing process, processing pertaining to a first-color color filter producing process, processing pertaining to a second-color color filter producing process, and processing pertaining to a third-color color filter producing process, and processing pertaining to a partition producing process are sequentially performed. Any of the first-color, second-color, and third-color color filters can also be produced outside an effective pixel area as the light blocking layer 113. A process for producing only the light blocking layer 113 can be omitted, so that manufacturing costs can be curtailed. Processing pertaining to the partition producing process can be performed at any phase subsequent to the light blocking layer producing process, the first-color color filter producing process, the second-color color filter producing process, and the third-color color filter producing process. Selection of a phase can be performed, as appropriate, by combination of manufacturing techniques and manufacturing methods utilized.

(Passivation Layer)

The passivation layer 110 is formed by means of an atomic layer deposition (ALD) technique. The atomic layer deposition technique is one type of CVD techniques and for producing a thin film by alternately iterating operation for letting an organic metal compound molecule, a metal halogen compound molecule, and a metallic hydrogen compound molecule to serve as a thin film material adsorb or react with a surface of the substrate and operation for decomposing unreacted radicals included in the molecules. Since a state of low molecules is achieved when the thin film material arrives at the surface of the substrate, the thin film can grow, so long as there exists a nominal space into which the low molecules can get. Therefore, complete coating of irregularities (a thin film grown on the irregularities has the same thickness as that of a thin film grown on a flat area), which has hitherto been difficult to perform under a related art thin film producing technique, is carried out; namely, extremely superior coatability, is exhibited. Minute defects in structures on a surface of a substrate, minute defects in the surface of the substrate, and irregularities due to particles adhering to the surface of the substrate can be completely coated. Therefore, such irregularities do not act as an intrusion path for a factor of degradation of a photoelectric conversion material. When the passivation layer 110 is formed by means of the atomic layer deposition technique, the thickness of the required passivation layer 110 can be reduced more effectively when compared with the related art technique.

When the passivation layer 110 is formed by the atomic layer deposition technique, a material appropriate for ceramic which is preferable for the foregoing passivation layer 110 can be selected, as required, and the material is limited to one that enables growth of a thin film at a relatively low temperature at which an organic material will not be degraded. Under the atomic layer deposition technique that uses, as a material, alkyl aluminum and aluminum halide, a dense aluminum oxide thin film can be produced at a temperature of less than 200 degrees Celsius at which an organic material is not degraded. In particular, when trimethyl aluminum is used, a thin aluminum oxide film can preferably be produced even at a temperature of 100 degrees Celsius or thereabouts. It is also preferable that a dense thin film can be produced at a temperature of less than 200 degrees Celsius, as in the case of the aluminum oxides, so long as a material is appropriately selected from silicon oxides and titanium oxides.

### Embodiments

Imaging devices of embodiments and imaging devices of comparative examples are hereunder used as samples. A step provided at an end of each of the pixel electrodes is defined, and an effect which is yielded as a result of provision of a passivation layer is now verified.

Imaging devices produced along procedures provided below are used as imaging devices that serve as samples. The imaging devices of respective embodiments have the same configuration except that the imaging devices are different from each other in terms of any of a configuration of a passivation layer, a height of an end of each of pixel electrodes, and an angle of the end.

First, read circuits 116, a wiring layer including connection blocks 105, an insulation layer 102 and pixel electrodes 104 are formed on a substrate 101 in standard CMOS image sensor process. Each size of the pixel electrodes is 3 μm. Angles and heights of steps (i.e., thicknesses of the pixel electrodes) achieved in the embodiments and the comparative examples will be described later. And, in an organic deposition chamber, the interior of the chamber is depressurized to 1×10⁻⁴ Pa or less. Subsequently, by means of a resistive heating deposition technique, an electron blocking layer is deposited to a thickness of 100 nm on the respective pixel electrodes at a deposition rate of 10 to 12 nm/s while a holder holding the substrate is rotated. A material (fullerene 60) designated by Chemical Formula 1 and a material designated by Chemical Formula 2 are subjected to co-deposition respectively at a deposition rate of 16 to 18 nm/s and a deposition rate of 25 to 28 nm/s in such a way that a volumetric ratio of Chemical Formula 1 to Chemical Formula 2 comes to 1:3, thereby producing an organic photoelectric conversion layer. Thickness of the organic photoelectric conversion layer is 400 nm. The substrate is then conveyed to a sputtering chamber, where an ITO film that is to become a counter electrode is formed to a thickness of 10 nm on the organic photoelectric conversion layer by means of RF magnetron sputtering.

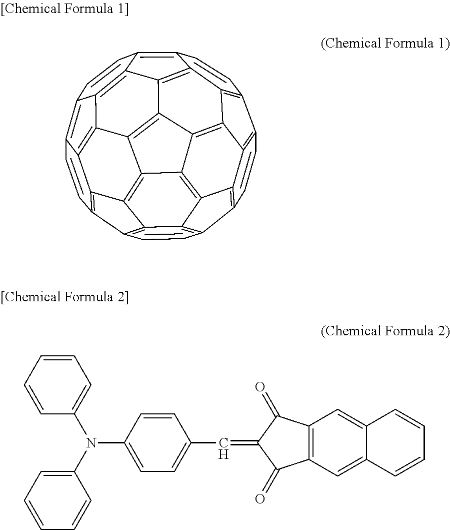

The substrate is then conveyed to an ALD film growth chamber, where a passivation layer is produced on the ITO film that is the counter electrode. Configurations of the passivation layers of the embodiments and configurations of the passivation layers of the comparative examples will be described later.

A SiON film among the plurality of layers making up the passivation layer is grown by means of introducing an Ar gas or an N₂ gas and through use of the RF magnetron sputtering technique while SiO is taken as a target. The SiO layer among the plurality of layers making up the passivation layer is grown by use of a resistive heating deposition technique while SiO is taken as a deposition source. Further, a SiN film is grown by means of introducing the Ar gas and the N₂ gas and through the RF magnetron sputtering technique while Si₃O₄ is taken as a target.

An AlO film is grown by use of trimethyl aluminum and water and by means of the atomic deposition technique.

When the imaging devices are fabricated as mentioned above and when an external electric field is applied to the organic photoelectric conversion layer while light originated from a DC light source onto the exposed imaging devices, DC output images and images output under dark conditions are acquired. An imaging lens used for capturing an image in conditions of light from the DC light source is a single focus lens at an aperture of F=5.6. The imaging lens is used while equipped with an IR block filter and a 50% transmission ND filter.

Film stress is measured at room temperature and in the atmosphere by use of FLX-2320 manufactured by KLA-Tencor Co., Ltd, by means a thin film stress measurement technique; namely, a technique for measuring a change in curvature radius of a substrate occurred before and after deposition of a thin film by means of a laser scan.

In relation to film stress of the passivation layer, stress for effecting a pull in a direction parallel to a surface of an organic film and a surface of a pixel electrode is taken as a positive direction, and stress for effecting compression in the direction parallel to the surface of the organic film and the surface of the pixel electrode is taken as a negative direction.

Table 1 provided below provides configurations of the respective sample passivation layers, film stress (MPa) of the films, angles (degree) of end side surfaces of the respective pixel electrodes, heights of steps of the respective pixel electrodes, and proportions of white flaw defects. The proportions of white flaw defects are represented by a value determined by dividing the number of pixel blocks subjected to white flaw defects by 100. When an output produced under dark conditions is 4 mV or more, the white flaw defects are determined to have occurred in pixel blocks of interest.

TABLE 11

| | | Film | | | |
|---|---|---|---|---|---|
| | Configuration of a passivation | stress | Angle | Height | Proportion |
| | layer | (MPa) | (degree) | (nm) | (%) |
| First | AlO(100)/SiON(100) | −20 | 90 | 40 | 0.034 |
| Embodiment | | | | | |
| Second | SiON(100)/AlO(200)/SiON(100) | −100 | 90 | 40 | 0.083 |
| Embodiment | | | | | |
| Third | SiON(100)/AlO(175)/SiON(100) | −200 | 90 | 40 | 0.96 |
| Embodiment | | | | | |
| Fourth | SiON(100)/AlO(200)/SiN(100) | 100 | 90 | 40 | 0.053 |
| Embodiment | | | | | |
| Fifth | SiON(50)/AlO(200)/SiON(100) | 125 | 90 | 40 | 0.71 |
| Embodiment | | | | | |
| Sixth | SiON(100)/AlO(200) | 175 | 90 | 40 | 0.012 |
| Embodiment | | | | | |
| Seventh | SiO(100)/AlO(200)/SiON(100) | 200 | 90 | 40 | 0.2 |
| Embodiment | | | | | |
| Eighth | SiON(100)/AlO(300) | 250 | 90 | 40 | 0.84 |
| Embodiment | | | | | |
| Comparative | AlO(50)/SiON(100) | −250 | 90 | 40 | 3.5 |
| Example 1 | | | | | |
| Comparative | SiON(50)/AlO(200) | 288 | 90 | 40 | 11 |
| Example 2 | | | | | |
| Comparative | AlOx(200) | 400 | 90 | 40 | 10.7 |
| Example 3 | | | | | |
| Reference | AlOx(200) | 400 | 0 | 0 | 0.002 |
| Example 1 | | | | | |
| Reference | AlOx(200) | 400 | 15 | 70 | 0.002 |
| Example 2 | | | | | |

In the Table 1, Film stress indicates film stress of the passivation layer (MPa), Angle (degree) indicates angle of an end side surface of a pixel electrode, Height (nm) indicates height of a step of the pixel electrode, and Proportion (%) indicates proportion of the number of pixels subjected to white flaw defects, respectively.

In the first embodiment, an AlO film is grown to a thickness of 100 nm, and a SiON film is grown to a thickness of 100 nm, in this sequence, on the counter electrode, to thus produce a passivation layer. Film stress of the entire passivation layer is −20 MPa. An angle of an end side surface of a pixel electrode is 90-degree, and a height of a step of the end side surface of the pixel electrode is 40 nm. Additionally, the angle and the height are measured by a cross-section image of transmission electron microscope as shown in FIG. 4.

In the second embodiment, a SiON film is grown to a thickness of 100 nm, an AlO film is grown to a thickness of 200 nm, and a SiON film is grown to a thickness of 100 nm, in this sequence, on the counter electrode, to thus produce a passivation layer. Film stress of the entire passivation layer is −100 MPa. An angle of an end side surface of a pixel electrode is 90-degree, and a height of a step of the end side surface of the pixel electrode is 40 nm.

In the third embodiment, a SiON film is grown to a thickness of 100 nm, an AlO film is grown to a thickness of 175 nm, and a SiON film is grown to a thickness of 100 nm, in this sequence, on the counter electrode, to thus produce a passivation layer. Film stress of the entire passivation layer is −200 MPa. An angle of an end side surface of a pixel electrode is 90-degree, and a height of a step of the end side surface of the pixel electrode is 40 nm.

In the fourth embodiment, a SiON film is grown to a thickness of 100 nm, an AlO film is grown to a thickness of 200 nm, and a SiN film is grown to a thickness of 100 nm, in this sequence, on the counter electrode, to thus produce a passivation layer. Film stress of the entire passivation layer is 100 MPa. An angle of an end side surface of a pixel electrode is 90-degree, and a height of a step of the end side surface of the pixel electrode is 40 nm.

In the fifth embodiment, a SiON film is grown to a thickness of 50 nm, an AlO film is grown to a thickness of 200 nm, and a SiON film is grown to a thickness of 100 nm, in this sequence, on the counter electrode, to thus produce a passivation layer. Film stress of the entire passivation layer is 125 MPa. An angle of an end side surface of a pixel electrode is 90-degree, and a height of a step of the end side surface of the pixel electrode is 40 nm.

In the sixth embodiment, a SiON film is grown to a thickness of 100 nm, and an AlO film is grown to a thickness of 200 nm, in this sequence, on the counter electrode, to thus produce a passivation layer. Film stress of the entire passivation layer is 175 MPa. An angle of an end side surface of a pixel electrode is 90-degree, and a height of a step of the end side surface of the pixel electrode is 40 nm.

In the seventh embodiment, a SiO film is grown to a thickness of 100 nm, an AlO film is grown to a thickness of 200 nm, and a SiON film is grown to a thickness of 100 nm, in this sequence, on the counter electrode, to thus produce a passivation layer. Film stress of the entire passivation layer is 200 MPa. An angle of an end side surface of a pixel electrode is 90-degree, and a height of a step of the end side surface of the pixel electrode is 40 nm.

In the eighth embodiment, a SiON film is grown to a thickness of 100 nm, and an AlO film is grown to a thickness of 300 nm, in this sequence, on the counter electrode, to thus produce a passivation layer. Film stress of the entire passivation layer is 250 MPa. An angle of an end side surface of a pixel electrode is 90-degree, and a height of a step of the end side surface of the pixel electrode is 40 nm.

In Comparative Example 1, an AlO film is grown to a thickness of 50 nm, and a SiON film is grown to a thickness of 100 nm, in this sequence, on the counter electrode, to thus produce a passivation layer. Film stress of the entire passivation layer is −250 MPa. An angle of an end side surface of a pixel electrode is 90-degree, and a height of a step of the end side surface of the pixel electrode is 40 nm.

In Comparative Example 2, a SiON film is grown to a thickness of 50 nm, and an AlO film is grown to a thickness of 200 nm, in this sequence, on the counter electrode, to thus produce a passivation layer. Film stress of the entire passivation layer is 288 MPa. An angle of an end side surface of a pixel electrode is 90-degree, and a height of a step of the end side surface of the pixel electrode is 40 nm.

In Comparative Example 3, an AlO film is grown to a thickness of 200 nm in sequence on the counter electrode, to thus produce a passivation layer. Film stress of the entire passivation layer is 400 MPa. An angle of an end side surface of a pixel electrode is 90-degree, and a height of a step of the end side surface of the pixel electrode is 40 nm.

In Reference Example 1, an AlO film is grown to a thickness of 200 nm in sequence on the counter electrode, to thus produce a passivation layer. Film stress of the entire passivation layer is 400 MPa. Pixel electrodes are fabricated within the insulation layer in such a way that lower surfaces of the respective pixel electrodes become flush with an upper surface of the insulation layer. An angle of an end side surface of the pixel electrode achieved at this time is 0-degree, and a height of a step of the end side surface of the pixel electrode is 0 nm.

In Reference Example 2, an AlO film is grown to a thickness of 200 nm in sequence on the counter electrode, to thus produce a passivation layer. Film stress of the entire passivation layer is 400 MPa. An angle of an end side surface of a pixel electrode is 15-degree, and a height of a step of the end side surface of the pixel electrode is 70 nm.

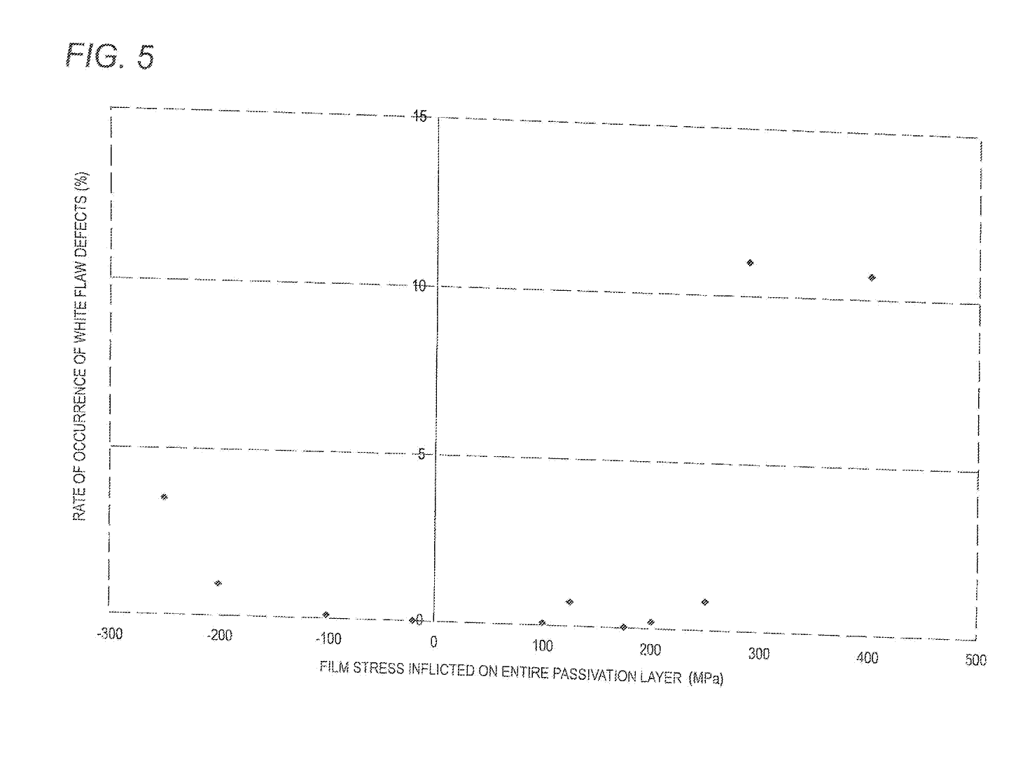

FIG. 5 is a graph in which a value determined by dividing film stress of the passivation layer (the number of pixel blocks where white flaw defects occurred) by 100 is plotted. In the graph, a horizontal axis represents film stress of the passivation layer (MPa), and a vertical axis represents a value determined by dividing (the number of pixel blocks where white flaw defects occurred) by 100.

In the imaging devices, the film stress of the passivation layers ranges from −200 MPa to 250 MPa. It is understood that, when the angle of the end side surface of the pixel electrode is 45-degree or more, the number of pixel blocks where the white flaw defects occurred can be sufficiently reduced.

The present patent specification provides a disclosure of the following matters.

(1) An imaging device includes a plurality of lower electrodes, an upper electrode, an organic photoelectric conversion layer and a passivation layer. The plurality of lower electrodes are arranged in a two dimensional pattern above a substrate. The upper electrode is arranged above the plurality of lower electrodes so as to oppose the lower electrodes. The organic photoelectric conversion layer is sandwiched between the plurality of lower electrodes and the upper electrode. The passivation layer is provided above the upper electrode and covers the upper electrode. An angle which an end side surface of the lower electrode forms with respect to a surface of a lower layer supporting the lower electrode is 45-degree or more. The passivation layer is formed from a plurality of layers. Film stress of the entire passivation layer ranges from −200 MPa to 250 MPa.

(2) The imaging device according to (1), the plurality of layers include an AlO film and any one of a SiO film, a SiON film, and a SiN film.

(3) The imaging device according to (1) or (2), when any one of the SiO film, the SiON film, and the SiN film is taken as a first film, the plurality of layers are formed by stacking the AlO film and the first film in sequence.

(4) The imaging device according to (1) or (2), the plurality of layers are formed by staking (i) any one of the SiO film, the SiON film, and the SiN film and (ii) the AlO film in sequence.

(5) The imaging device according to (1) or (2), when any one of the SiO film, the SiON film, and the SiN film is taken as a first film and when any one of the SiO film, the SiON film, and the SiN film is taken as a second film, the plurality of layers are formed by stacking the first film, the AlO film, and the second film in sequence.

(6) The imaging device according to any one of (1) to (5), film stress of the entire passivation layer ranges from −100 MPa to 200 MPa.

(7) The imaging device according to any one of (1) to (6), the angle which the end side surface of the lower electrode forms with respect to the surface of the lower layer supporting the lower electrode is 60-degree or more.

(8) The imaging device according to any one of (1) to (7), the angle which the end side surface of the lower electrode forms with respect to the surface of the lower layer supporting the lower electrode is 80-degree or more.

What is claimed is:

1. An imaging device comprising:
a plurality of lower electrodes that are arranged in a two dimensional pattern above a substrate;
an upper electrode that is arranged above the plurality of lower electrodes so as to oppose the lower electrodes;
an organic photoelectric conversion layer that is sandwiched between the plurality of lower electrodes and the upper electrode; and
a passivation layer that is provided above the upper electrode and that covers the upper electrode,
wherein an angle which an end side surface of the lower electrode forms with respect to a surface of a lower layer supporting the lower electrode is 45-degree or more,
the passivation layer is formed from a plurality of layers, and
film stress of the entire passivation layer ranges from −200 MPa to 250 MPa.

2. The imaging device according to claim 1,
wherein the plurality of layers include an AlO film and any one of a SiO film, a SiON film, and a SiN film.

3. The imaging device according to claim 1,
wherein, when any one of the SiO film, the SiON film, and the SiN film is taken as a first film, the plurality of layers are formed by stacking the AlO film and the first film in sequence.

4. The imaging device according to claim 1,
wherein the plurality of layers are formed by staking (i) any one of the SiO film, the SiON film, and the SiN film and (ii) the AlO film in sequence.

5. The imaging device according to claim 1,
wherein, when any one of the SiO film, the SiON film, and the SiN film is taken as a first film and when any one of the SiO film, the SiON film, and the SiN film is taken as a second film, the plurality of layers are formed by stacking the first film, the AlO film, and the second film in sequence.

6. The imaging device according to claim 1,
wherein film stress of the entire passivation layer ranges from −100 MPa to 200 MPa.

7. The imaging device according to claim 1,
wherein the angle which the end side surface of the lower electrode forms with respect to the surface of the lower layer supporting the lower electrode is 60-degree or more.

8. The imaging device according to claim 1,
wherein the angle which the end side surface of the lower electrode forms with respect to the surface of the lower layer supporting the lower electrode is 80-degree or more.
